(19) United States
(12) Patent Application Publication
(10) Pub. No.: US 2007/0111346 A1
(43) Pub. Date: May 17, 2007

(54) Laser-marking method for a wafer

(76) Inventor: Yu-Pen Tsai, Kaohsiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/543,195

(22) Filed: Oct. 5, 2006

(30) Foreign Application Priority Data
Nov. 14, 2005 (TW) 094139968

(51) Int. Cl. H01L 21/00

(52) U.S. Cl. 438/22

(57) ABSTRACT

The present invention relates to a laser-marking method for a wafer. The method of the invention comprises the steps of: (a) providing a wafer, the wafer having a first surface and a second surface, and a glue layer disposed on the first surface; (b) attaching the glue layer under a first film, the first film installed on a frame; and (c) projecting a laser light on the second surface of the wafer to mark the wafer. By utilizing the frame, the supporting force can be larger and orientation of the laser can be improved so as to improve the precision for marking the wafer and improve the quality of products.

### BACKGROUND OF THE INVENTION

1. Field of the Invention

The invention relates to a laser-marking method for a wafer, particularly to a laser-marking method using a frame to support the wafer.

2. Description of the Related Art

Referring to FIGS. 1A to 1D, they show a conventional laser-marking method for a wafer. Referring to FIG. 1A, firstly, a wafer 10 is provided. The wafer 10 has a first surface 101 and a second surface 102, and a plurality of bumps 103 are disposed on the first surface 101. A glue layer 11 is disposed on the first surface 101. Referring to FIG. 1B, the wafer 10 is ground to be thinner. Referring to FIG. 1C, the glue layer 11 is attached on a first film 12, and a laser light 13 is projected on the second surface 102 of the wafer 10 to mark the wafer 10. Referring to FIG. 1D, finally, the wafer 10 is cut to form a plurality of chips 14.

In the conventional laser-marking method, the first film 12 is not installed on a frame so that the thinned wafer 10 cannot obtain a larger supporting force to support the wafer and the orientation of the laser light 13 cannot be improved. Therefore, the precision for marking the wafer 10 and the quality of products cannot be ensured. In addition, without the frame protection, the thinned wafer 10 is easily broken when the wafer 10 is moved to the printing stage.

Consequently, there is an existing need for providing a laser-marking method for a wafer to solve the above-mentioned problems.

### SUMMARY OF THE INVENTION

One objective of the present invention is to provide a laser-marking method for a wafer. The laser-marking method of the invention comprises the steps of: (a) providing a wafer, the wafer having a first surface and a second surface, and a glue layer disposed on the first surface; (b) attaching the glue layer under a first film, the first film installed on a frame; and (c) projecting a laser light on the second surface of the wafer to mark the wafer.

In the invention, the first film is installed on a frame so that the thinned wafer can obtain a larger supporting force. Therefore, by utilizing the frame, the supporting force is offered and the orientation of the laser can be improved, so that the precision for marking the wafer and the quality of products can be improved. In addition, the thinned wafer is protected from colliding by the frame, so that the wafer can be prevented from breaking when moved to the printing stage.

### BRIEF DESCRIPTION OF THE DRAWINGS

FIGS. 1A to 1D show a conventional laser-marking method for a wafer;

FIGS. 2A to 2G show a laser-marking method for a wafer according to the present invention.

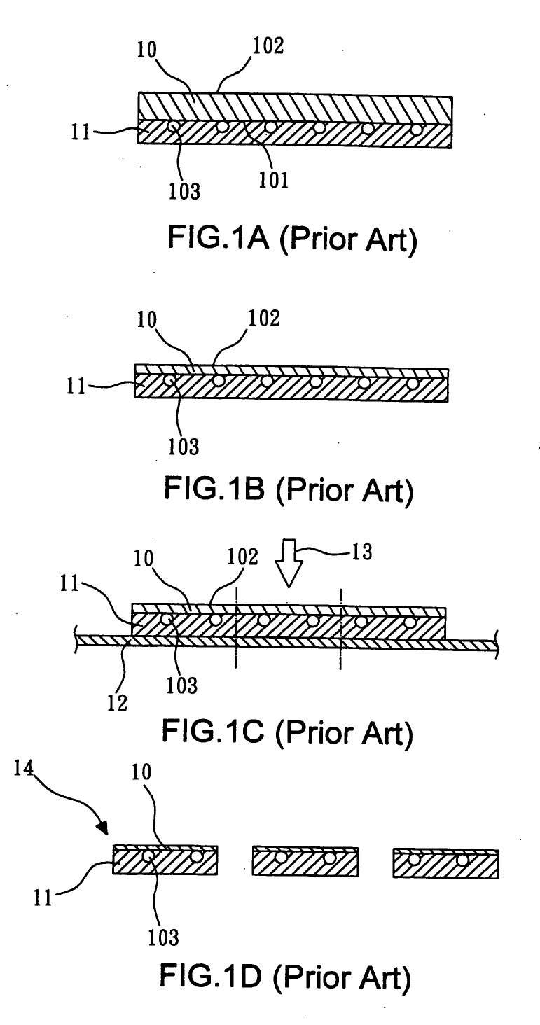

### DETAILED DESCRIPTION OF THE INVENTION

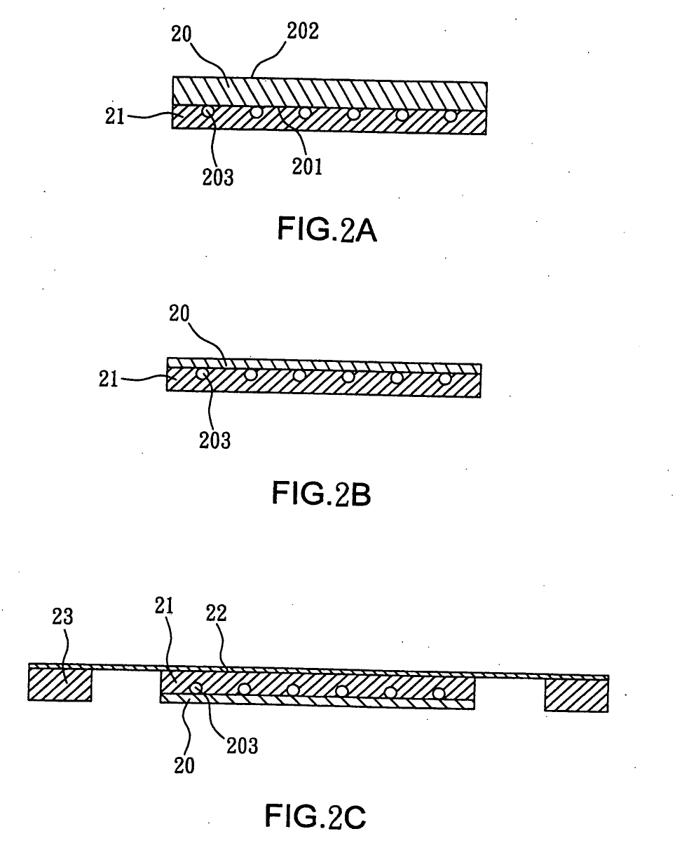

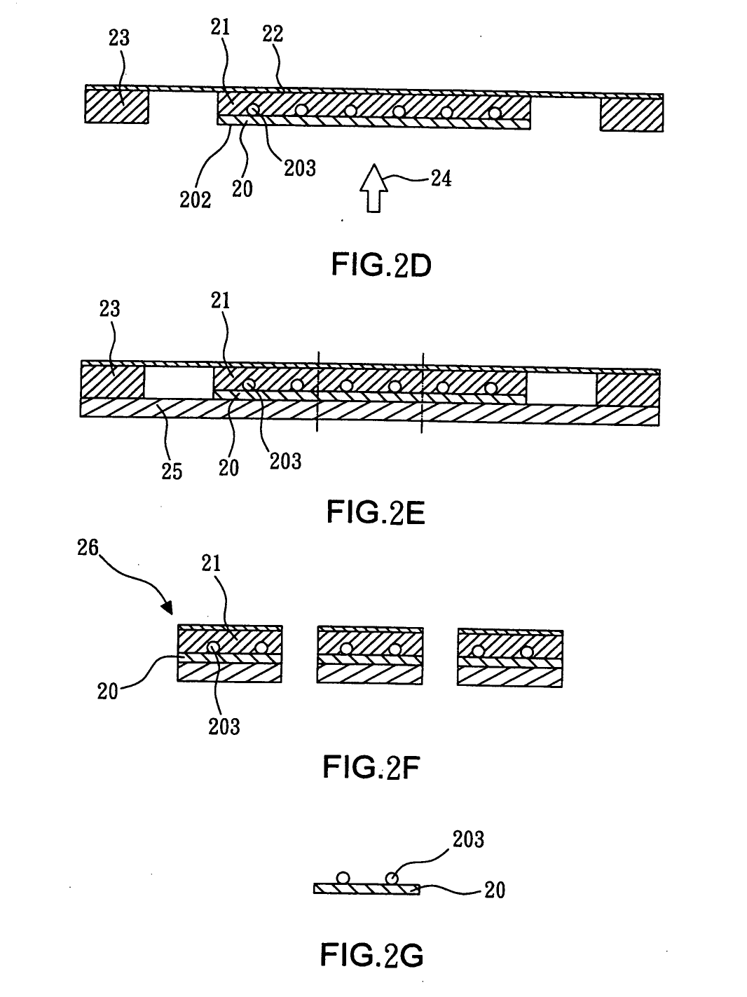

Referring to FIGS. 2A to 2G, they show a laser-marking method for a wafer according to the present invention. Referring to FIG. 2A, firstly, a wafer 20 is provided. The wafer 20 has a first surface 201 and a second surface 202, and a plurality of bumps 203 are disposed on the first surface 201. A glue layer 21 is disposed on the first surface 201, and the glue layer 21 is a transparent material. Referring to FIG. 2B, the wafer 20 is ground to be thinner.

Referring to FIG. 2C, the glue layer 21 is attached on a first film 22, and the first film 22 is installed on a frame 23. The shape of the frame 23 matches the shape of the wafer 20. The first film 22 is a transparent material. The frame 23 is used to protect the wafer 20 to prevent breaking. Referring to FIG. 2D, a laser light 24 is projected on the second surface 202 of the wafer 20 to mark the wafer 20, wherein the frame 23 is used to position the laser light 24. The laser light 24 moves co-axially with an image device (not shown) located on the other side of the wafer 20 to proceed the marking step. Before the wafer 20 is marked, at least one positioning point (not shown) is formed on the second surface 202. Referring to FIG. 2E, the wafer 20 and the frame 23 are attached on a second film 25. Referring to FIG. 2F, the frame 23 is removed, and then the wafer 20 is cut to form a plurality of chips 26 by using a laser. Referring to FIG. 2G, finally, the wafer 20 is segregated from the first film 22 and second film 25.

In the invention, the first film 22 is installed on the frame 23 so that the thinned wafer 20 can obtain a larger supporting force. Therefore, by utilizing the frame 23, a supporting force for the wafer 20 is offered and the orientation of the laser light 24 can be improved, so that the precision for marking the wafer 20 and the quality of products can be improve. In addition, the thinned wafer 20 is protected from colliding by the frame 23, so that the wafer 20 can be prevented from breaking when moved to the printing stage.

While the embodiment of the present invention has been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

What is claimed is:

1. A laser-marking method for a wafer, the laser-marking method comprising the steps of:
(a) providing a wafer, the wafer having a first surface and a second surface, and a glue layer disposed on the first surface;
(b) attaching the glue layer under a first film, the first film installed on a frame; and
(c) projecting a laser light on the second surface of the wafer to mark the wafer.

2. The method according to claim 1, further comprising a step of attaching the wafer and the frame on a second film after the step (b).

3. The method according to claim 1, wherein the first film is a transparent material.

4. The method according to claim 1, wherein the glue layer is a transparent material.

5. The method according to claim 1, further comprising a step of forming at least one positioning point on the second surface before the step (c).

6. The method according to claim 1, wherein the laser light moves co-axially with an image device located on the other side of the wafer in the step (c).

7. The method according to claim 1, further comprising a step of forming a plurality of chips by cutting the wafer using a laser after the step (c).

8. The method according to claim 1, wherein a plurality of bumps are disposed on the first surface of the wafer.

9. The method according to claim 1, wherein the shape of the frame matches the shape of the wafer.

10. The method according to claim 1, wherein the frame is used to protect the wafer to prevent breaking.

11. The method according to claim 1, wherein the frame is used to position the laser.

12. The method according to claim 1, further comprising a grinding step to thin the wafer after the step (a).

13. The method according to claim 7, further comprising a step of segregating the wafer from the first film and the second film after the step (c).
